(19) United States
(12) Patent Application Publication
(10) Pub. No.: US 2026/0269197 A1
(43) Pub. Date: Sep. 10, 2026

(54) CLEANING PROCESS FOR PLASMA PROCESS CHAMBER

(71) Applicant: Taiwan Semiconductor Manufacturing Company, LTD., Hsinchu (TW)

(72) Inventors: Sun-Chen Hua, Taipei (TW); Shao Hsuan Yang, Taoyuan (TW); Tai-Ling Yang, Hsinchu (TW); Che-Cheng Chang, New Taipei (TW)

(21) Appl. No.: 19/073,175

(22) Filed: Mar. 7, 2025

(51) Int. Cl. H01J 37/32

(52) U.S. Cl. CPC H01J 37/32853; H01J 37/32119; H01J 37/32449; H01J 2237/334

(57) ABSTRACT

A chamber cleaning process includes flowing a gas mixture comprising a nitrogen tetrafluoride or another halogen-containing gas into a plasma process chamber, and exciting the halogen-containing gas to form a first plasma in the plasma process chamber by applying first radio frequency (RF) power to the halogen-containing gas using an RF generator operatively coupled with the plasma process chamber. Thereafter, oxygen gas is flowed into the plasma process chamber, and the oxygen gas is excited to form a second plasma in the plasma process chamber by applying second RF power to the oxygen gas using the RF generator. The chamber cleaning process does not include flowing silicon tetrachloride into the plasma process chamber. After completion of the chamber cleaning process, a semiconductor wafer may be loaded into the plasma process chamber, and a silicon etching process is performed on the semiconductor wafer.

### BACKGROUND

The following relates to the semiconductor processing arts, to semiconductor processing plasma chambers and cleaning of same, to semiconductor processing fabrication facility (fab) workflows, and the like.

A semiconductor processing plasma chamber may be used to perform certain processing steps in an integrated circuit (IC) or other semiconductor fabrication workflow, such as an etching step or a material deposition step. For example, a plasma etching chamber may be used to etch polycrystalline silicon (i.e., polysilicon), optionally using photolithographic control to define the areas etched. Such polysilicon etch back is a process used in silicon-based IC fabrication workflows.

After using the semiconductor processing plasma chamber to perform polysilicon etching or other processing of a semiconductor wafer (e.g., a silicon wafer, silicon-on-insulator wafer, gallium arsenide wafer, or so forth), or after processing a certain number of such wafers, a wafer-less auto-clean (WAC) process may be performed to clean the semiconductor processing plasma chamber. The WAC process may entail running the semiconductor processing plasma chamber without a wafer loaded using plasma produced by chamber settings such as radio frequency (RF) power, chamber pressure, gas composition, and/or so forth designed to clean the chamber. The WAC process may also include flowing a gas under plasma conditions effective to coat the walls of the semiconductor processing plasma chamber with a protective coating.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a plasma process chamber cleaning process according to a first embodiment.

FIG. 2 diagrammatically illustrates the plasma process chamber according to one nonlimiting illustrative configuration.

FIG. 3 diagrammatically illustrates a plasma process chamber cleaning process according to a second embodiment.

FIG. 4 diagrammatically illustrates plasma regions produced by the second embodiment (lefthand side) and by the first embodiment (righthand side).

FIG. 5 diagrammatically illustrates a method of using a plasma process chamber.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

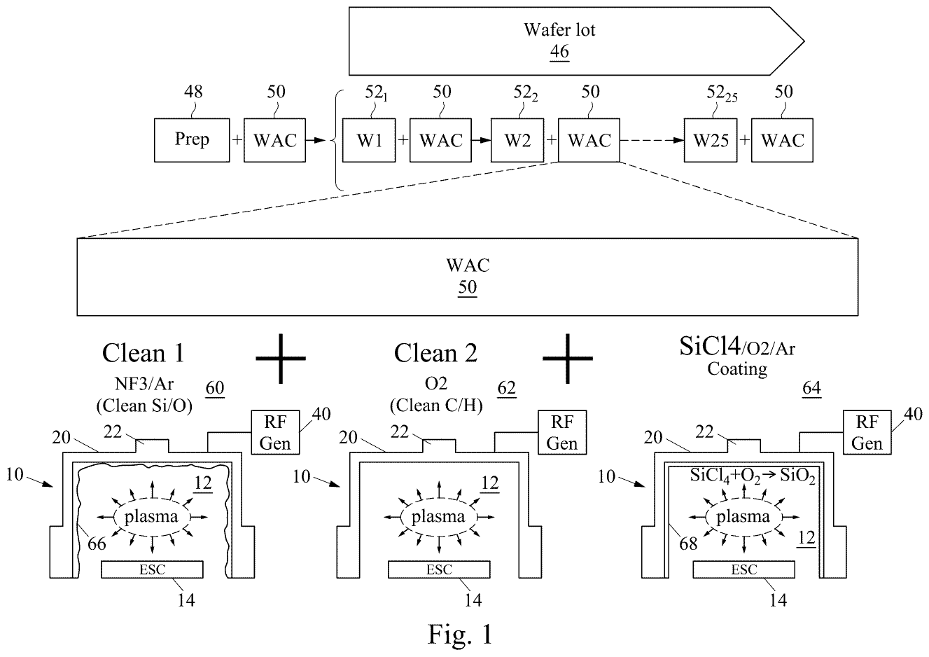

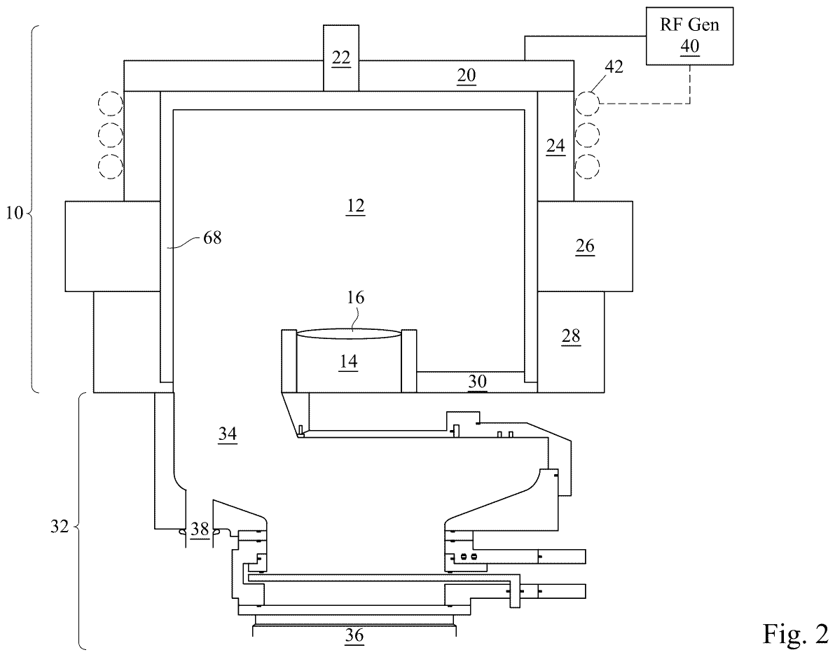

FIG. 1 diagrammatically illustrates a plasma process chamber cleaning process for cleaning a plasma process chamber 10, according to a first embodiment. FIG. 2 shows an enlarged and more detailed diagrammatic view of the plasma process chamber 10. As seen in FIG. 2, the plasma process chamber 10 has an interior volume 12, in a lower region of which is located a wafer holder 14 that is configured to hold a diagrammatically indicated semiconductor wafer 16 to be processed by a plasma formed in the interior volume 12. In some nonlimiting illustrative embodiments, the wafer holder 14 is (or includes) an electrostatic chuck (ESC) for holding the semiconductor wafer, but other wafer holding mechanisms such as a clamp or the like is contemplated. Optionally, the wafer holder 14 may include a mechanism for rotating the semiconductor wafer 16 during processing to improve uniformity. The plasma process chamber 10 includes structural components surrounding the interior volume 12. In the illustrative example, these include a transformer-coupled plasma (TCP) window 20 that includes at least one gas injector 22, a gas distribution plate (GDP) 24, an annular chamber sidewall 26, a lateral annular liner 28, and lower liner 30.

The plasma process chamber 10 is connected with a pumping section or line 32 (shown only in FIG. 2), which in the illustrative example is disposed underneath or below the plasma process chamber 10. The nonlimiting illustrative example pumping section or line 32 includes an exhaust line or path 34 connecting the interior volume 12 of the plasma process chamber 10 with a diagrammatically indicated turbomolecular pump (i.e., turbopump) 36. In operation, a gas mixture flows in through the at least one gas injector 22, through the gas distribution plate 24 and into the interior volume 12, and is exhausted (or pumped) by the turbopump 36 via the exhaust line or path 34. Initial rough pumping of the interior volume 12 to a pressure at which the turbopump 36 is operational is performed via a rough pumping line or path 38 to which a roughing pump (not shown) is connected. The skilled artisan will appreciate that FIG. 2 is diagrammatic, and that various additional components typically included, such as valves, are not shown. This gas flow arrangement of FIG. 2 is a nonlimiting illustrative example, and other configurations of the plasma process chamber 10 and pumping section or line 32 are contemplated. Furthermore, while in the above description the plasma process chamber 10 and pumping section or line 32 are referred to as separate assemblies connected by the exhaust line or path 34, they may alternatively be viewed as sub-assemblies of a single plasma process chamber (or stated another way, the pumping section or line 32 can alternatively be viewed as being part of the plasma process chamber, rather than a separate assembly connected therewith). It is further noted that the turbopump 36 could be replaced by another type of dry pump (for cleanliness), or by an oil-utilizing pump such as a diffusion pump.

A radio frequency (RF) generator 40 is connected with a transformer of the TCP window 14 to apply RF power to a gas mixture in the interior volume 12 using a transformer built into the TCP window 14. The RF power excites the gas mixture (or one or more gas components thereof) to form a plasma in the interior volume 12. Thus, this illustrative example is a TCP process chamber. More generally, the RF generator 40 is operatively connected to apply RF power to a gas mixture in the interior volume 12 to excite the gas mixture (or one or more gas components thereof) to form a plasma in the interior volume 12. The operative connection of the RF generator 40 to apply the RF power can take various forms besides the illustrative TCP connection (i.e., coupling). In another example, illustrated in FIG. 2 using dashed lines, the RF generator 40 is inductively coupled with the plasma process chamber 10 via an induction coil 42, in which case the plasma process chamber 10 employs an inductively coupled plasma (ICP) and may in this case be referred to as an ICP chamber. Other approaches for operatively connecting the RF generator 40 to apply the RF power are contemplated, such as an electron cyclotron resonance (ECR) connection (i.e., coupling), use of RF electrodes disposed in the interior volume 12 (for example, with one RF electrode integrated into the upper window and another integrated into the wafer holder), with the RF electrodes connected with the RF generator by RF cables and suitable RF feedthroughs of the plasma process chamber, or so forth.

When used for semiconductor wafer processing, a suitable process gas mixture is flowed into the interior volume 12 via the at least one gas injector 22. The gas mixture may include one or more reaction gases, and may also include an inert carrier gas such as argon (Ar), nitrogen (N₂), or so forth. The RF generator 40 applies RF power to excite one or more gases of the gas mixture to form a plasma in the plasma process chamber 10 (i.e., in the interior 12 thereof). The plasma includes ionized gas atoms and/or molecules that more readily react with the surface of the semiconductor wafer 16. Depending on the composition of the gas mixture, the resulting processing can be deposition of material by (net) adhesion of the ionized gas atoms and/or molecules, or etching of material by (net) removal of material by interaction with the ionized gas atoms and/or molecules.

In some illustrative examples herein, the wafer processing performed is silicon etching, for example using a gas mixture comprising a halogen-containing gas and a carrier gas. For example, the halogen-containing gas could be chlorine (Cl₂) gas which when excited to form a plasma produces chlorine ions; or hydrogen bromide (HBr) gas which when excited to form a plasma produces bromine ions; or a fluorocarbon gas which when excited to form a plasma produces fluorine ions. The RF power applied by the RF generator forms the plasma comprising halogen ions. Silicon etching can occur by chemical reaction of the halogen ions with silicon material on the semiconductor wafer 16, and/or by physical sputtering of the silicon material by energetic ions of the plasma. One type of silicon etching is polycrystalline silicon (i.e., polysilicon) etch-back, sometimes denoted by the acronym POEB.

While the plasma-generated ions are beneficial for the wafer processing, they create a challenging environment for maintaining surfaces of the plasma process chamber 10 which are exposed to the plasma formed in the interior 12 of the plasma process chamber 10. Certain types of surfaces, such as aluminum or aluminum alloy surfaces, certain ceramic surfaces, or so forth, are susceptible to plasma-induced damage, and such damage can also produce particles or particulates that can contaminate the semiconductor wafer 16 undergoing processing.

To protect these surfaces which are susceptible to damage when exposed to the plasma formed in the chamber interior 12, a protective yttrium oxide (Y₂O₃) coating is disposed on the surfaces. For example, yttrium oxide coatings are applied to the surface of the TCP window 20 which is exposed to the plasma, to (at least) portions of the gas injector 22 which are exposed to the plasma, and to the surface or surfaces of the gas distribution plate 24 which are exposed to the plasma.

A plasma process chamber cleaning process for cleaning the plasma process chamber 10 is diagrammatically shown in FIG. 1 as a time flow diagram. As there shown, prior to processing of semiconductor wafers (e.g., a quantity of wafers designated as a “Wafer Lot” 46 in FIG. 1), initial chamber preparation 48 may be performed, such as calibration, manual cleaning of surfaces of the interior 12, and/or so forth. This is followed by a first waferless auto-clean (WAC) process 50. This cleaning process is “wafer-less” because it is performed without a semiconductor wafer loaded into the plasma process chamber 10 (that is, no wafer is being held by the wafer holder 14 during the WAC process 50). The WAC process 50 is an automatic cleaning (i.e., auto-clean) insofar as it is performed by automated operation of flow of cleaning gases and/or gas mixtures and application of RF power via the RF generator 40, e.g., according to a pre-programmed recipe executed by a controller of the plasma process chamber 10. Some suitable embodiments of the WAC process 50 (which may more generally be referred to herein as a chamber cleaning process) will be described later herein.

After completion of the WAC process 50, a first semiconductor wafer 16 of the wafer lot 46 is loaded into the plasma process chamber 10 (that is, mounted onto the wafer holder 14 as shown in FIG. 2), and at least one plasma-assisted etching or deposition operation 521 is performed on that first semiconductor wafer 16. The loading of the first semiconductor wafer 16 may utilize an automated loading mechanism, such as a robotic wafer handling or transfer device operating in conjunction with an automated material handling system of the semiconductor fabrication facility (i.e., semiconductor fab) that delivers a front opening unified (or universal) pod (FOUP) containing the semiconductor wafers of the wafer lot 46 to a loading station of the plasma process chamber 10 for transfer of successive semiconductor wafers into the plasma process chamber 10 for processing (features not shown). This is merely an illustrative example.

In some illustrative embodiments, the at least one plasma-assisted etching or deposition operation 521 performed on the first semiconductor wafer loaded into the plasma process chamber 10 is a silicon etching operation, such as a polysilicon etch-back (POEB) operation. The silicon etching is performed by flowing a gas mixture into the interior 12 of the plasma process chamber 10 via the at least one gas injector 22. The gas mixture may comprise a halogen-containing gas (e.g., Cl₂ gas or HBr gas) and a carrier gas (e.g., Ar or N₂). The halogen-containing gas is excited to form a plasma by RF power applied by the RF generator 50 to perform the silicon etching. This is merely a nonlimiting illustrative example of one suitable embodiment of the at least one plasma-assisted etching or deposition operation 521.

After processing of the first semiconductor wafer of the wafer lot 46, the first semiconductor wafer is removed from the interior 12 of the plasma process chamber 10 (e.g., unloaded from the wafer holder 14 by the robotic apparatus previously used for loading the first semiconductor wafer). As seen in the time flow diagram of FIG. 1, this is followed by a second (instance of the) WAC process 50 to clean the interior 12 of the plasma process chamber 10 of any residual material and/or contamination left over from the at least one plasma-assisted etching or deposition operation 521 performed on the first semiconductor wafer. Thereafter, a second semiconductor wafer of the wafer lot 46 is loaded into the plasma process chamber 10, and at least one plasma-assisted etching or deposition operation 522 is performed on the second semiconductor wafer. As diagrammatically shown in the time flow diagram of FIG. 1, this process is repeated until a final semiconductor wafer of the wafer lot 46 is loaded (by way of nonlimiting illustrative example, in FIG. 1 the wafer lot 46 is assumed to have 25 wafers, but the number of wafers in the lot can be larger or small than 25), and at least one plasma-assisted etching or deposition operation 5225 is performed on the last semiconductor wafer of the wafer lot 46. In some examples, each of the at least one plasma-assisted etching or deposition operations 521, 522, . . . , 5225 is the same, e.g., each one is a POEB process in the illustrative example of performing a polysilicon etch-back step of a semiconductor fabrication workflow on the semiconductor wafers of the wafer lot 46. However, it is alternatively contemplated for the operations 521, 522, . . . , 5225 to be different operations.

With continuing reference to FIG. 1, the WAC process 50 is now described in further detail. The WAC process 50 of FIG. 1 includes a first cleaning step (“Clean 1”) 60, followed by a second cleaning step (“Clean 2”) 62, followed by a coating step 64. The illustrative first cleaning step 60 employs a gas mixture comprising a mixture of nitrogen trifluoride (NF₃) gas and a carrier gas such as argon (Ar); however, a mixture of another halogen-containing gas and a carrier gas is alternatively contemplated. For example, the halogen-containing gas could instead by chlorine (Cl₂) gas which when excited to form a plasma produces chlorine ions; or hydrogen bromide (HBr) gas which when excited to form a plasma produces bromine ions; or a fluorocarbon gas which when excited to form a plasma produces fluorine ions. The fluorine ions (or other halogen ions) operate to remove silicon or silicon oxide residue 66 from surfaces of the interior 12 of the plasma process chamber 10 by chemical reaction of the fluorine ions with the silicon or silicon oxide, and/or by physical sputtering of the silicon material by energetic ions of the plasma. In a nonlimiting illustrative example, parameters of the first cleaning step 60 in the illustrative case of a TCP process chamber may include: chamber pressure of about 400 mTorr; TCP RF power of about 1800 watts; transformer-coupled capacitive tuning (TCCT) setpoint of about 0.8; nitrogen trifluoride gas flow rate of about 500 sccm; carrier argon gas flow rate of about 200 sccm; and process time for the first cleaning step 60 of about 16 seconds. This is merely a nonlimiting illustrative example.

The illustrative second cleaning step 62 employs oxygen (O₂) gas. When excited to form a plasma, the oxygen gas produces oxygen ions which operate to remove residues of carbon or hydrocarbon compounds from surfaces of the interior 12 of the plasma process chamber 10 by chemical reaction of the oxygen ions with the carbon or hydrocarbon, and/or by physical sputtering of the carbon or hydrocarbon material by energetic oxygen ions of the plasma. In a nonlimiting illustrative example, parameters of the second cleaning step 62 in the illustrative case of a TCP process chamber may include: chamber pressure of about 15 mTorr; TCP RF power in a range of about 500-1500 watts; TCCT setpoint in a range of about 0.5 to 3; oxygen gas flow rate in a range of about 5 sccm to 400 sccm; and process time for the second cleaning step 62 in a range of about 5 seconds to 20 seconds. This is merely a nonlimiting illustrative example.

The illustrative coating step 64 employs a gas mixture comprising a mixture of silicon tetrachloride (SiCl₄) gas, oxygen (O₂) gas, and a carrier gas such as argon (Ar). When this gas mixture is excited to form a plasma, the silicon from the silicon tetrachloride and the oxygen react according to the reaction:

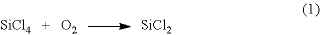

to deposit a coating of silicon dioxide (SiO₂) 68 on the interior 12 of the plasma process chamber 10, as shown in each of FIGS. 1 and 2. The purpose of the silicon dioxide coating 68 is to prevent the plasma produced during the at least one plasma-assisted etching or deposition operation 52₁ (or 52₂, . . . , 52₂₅) from attacking the surfaces of the interior 12 of the plasma process chamber 10. In particular, the silicon dioxide coating 68 blocks the plasma from reaching and attacking the yttrium oxide coatings of components that are susceptible to plasma damage, such as the TCP window 20, the at least one gas injector 22, and the gas distribution plate 24. Although the yttrium oxide coatings protect these sensitive surfaces, the yttrium oxide coatings themselves can undergo some plasma induced damage, thereby producing yttrium oxide particles or particulates that can damage the semiconductor wafer 16 processed after the WAC cleaning process 50. The silicon dioxide coating 68 blocks the plasma from reaching and attacking the yttrium oxide coatings, and thus reduces defect counts for the processed semiconductor wafers and improves device yield.

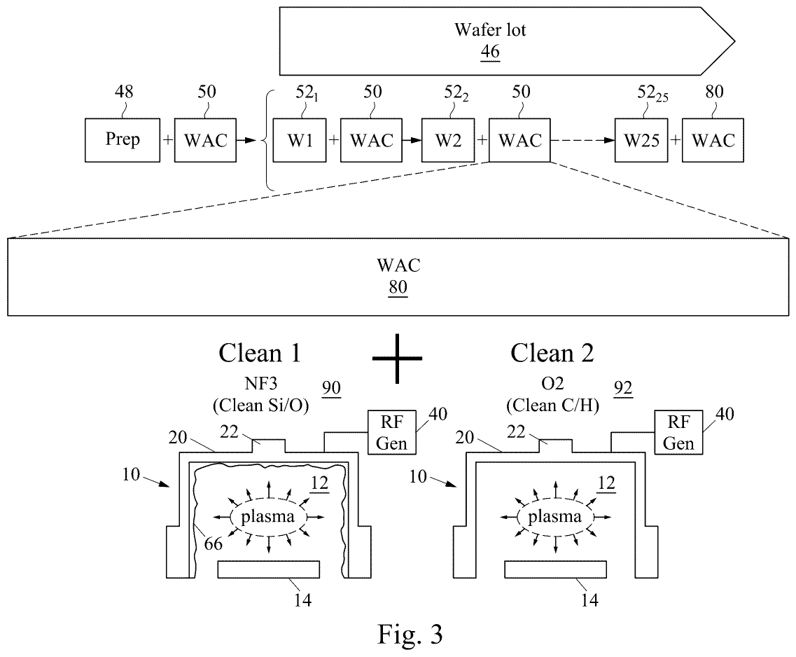

With reference now to FIG. 3, a plasma process chamber cleaning process for cleaning the plasma process chamber 10 according to another process is described. FIG. 3 includes the same time flow diagram as in FIG. 1, except that the WAC cleaning process 50 of the embodiment of FIG. 1, which employs silicon tetrachloride (SiCl₄) gas to perform the SiO₂ coating process 64, is replaced by a silicon tetrachloride-free WAC process 80. As shown in the time flow diagram as in FIG. 3, the workflow again performs processing, such as silicon etching (e.g., POEB) of a wafer lot 46, and the workflow optionally starts with initial chamber preparation 48 such as calibration, manual cleaning of surfaces of the interior 12, and/or so forth. This is followed by a first WAC process 80 which is “wafer-less” because it is performed without a semiconductor wafer loaded into the plasma process chamber 10 (that is, no wafer is being held by the wafer holder 14 during the WAC process 50). The WAC process 80 is an automatic cleaning (i.e., auto-clean) insofar as it is performed by automated operation of flow of cleaning gases and/or gas mixtures and application of RF power via the RF generator 40, e.g., according to a pre-programmed recipe executed by a controller of the plasma process chamber 10. After completion of the first WAC process 80, a first semiconductor wafer 16 of the wafer lot 46 is loaded into the plasma process chamber 10 (that is, mounted onto the wafer holder 14 as shown in FIG. 2), and at least one plasma-assisted etching or deposition operation 521 is performed on that first semiconductor wafer 16 as previously described with reference to FIG. 1. After processing of the first semiconductor wafer of the wafer lot 46, the first semiconductor wafer is removed from the interior 12 of the plasma process chamber 10 (e.g., unloaded from the wafer holder 14 by the robotic apparatus previously used for loading the first semiconductor wafer). As seen in the time flow diagram of FIG. 3, this is followed by a second (instance of the) WAC process 80 to clean the interior 12 of the plasma process chamber 10 of any residual material and/or contamination left over from the at least one plasma-assisted etching or deposition operation 521 performed on the first semiconductor wafer. Thereafter, a second semiconductor wafer of the wafer lot 46 is loaded into the plasma process chamber 10, and at least one plasma-assisted etching or deposition operation 522 is performed on the second semiconductor wafer. As diagrammatically shown in the time flow diagram of FIG. 3, this process is repeated until a final semiconductor wafer of the wafer lot 46 is loaded (by way of nonlimiting illustrative example, in FIG. 2 the wafer lot 46 is again assumed to have 25 wafers, but the number of wafers in the lot can be larger or small than 25), and at least one plasma-assisted etching or deposition operation 5225 is performed on the last semiconductor wafer of the wafer lot 46. In some examples, each of the at least one plasma-assisted etching or deposition operations 521, 52₂, . . . , 52₂₅ is the same, e.g., each one is a POEB process in the illustrative example of performing a polysilicon etch-back step of a semiconductor fabrication workflow on the semiconductor wafers of the wafer lot 46. However, it is alternatively contemplated for the operations 52₁, 52₂, . . . , 52₂₅ to be different operations.

As previously mentioned, the silicon tetrachloride-free WAC process 80 does not employ silicon tetrachloride gas. This is advantageous, because silicon tetrachloride is a corrosive and toxic gas. Silicon tetrachloride can be fatal if inhaled, and can produce burns of eyes, skin, and mucous membranes. In the United States, silicon tetrachloride is considered hazardous by the Occupational Safety and Health Administration (OSHA). Hence, it is advantageous that the WAC process 80 of the embodiment of FIG. 3 does not utilize silicon tetrachloride gas.

With continuing reference to FIG. 3, the silicon tetrachloride-free WAC process 80 is now described in further detail. The WAC process 80 of FIG. 3 includes a first cleaning step (“Clean 1”) 90, followed by a second cleaning step (“Clean 2”) 92. The first cleaning step 90 corresponds in functionality to the first cleaning step 60 of the WAC process 50—that is, it employs nitrogen trifluoride (NF₃) gas (or another halogen-containing gas) to remove silicon or silicon oxide residue 66 from surfaces of the interior 12 of the plasma process chamber 10 by chemical reaction of fluorine (or other halogen) ions with the silicon or silicon oxide, and/or by physical sputtering of the silicon material by energetic ions of the plasma. The second cleaning step 92 corresponds in functionality to the second cleaning step 62 of the WAC process 50—that is, it employs oxygen (O₂) gas to remove residues of carbon or hydrocarbon compounds from surfaces of the interior 12 of the plasma process chamber 10 by chemical reaction of the oxygen ions with the carbon or hydrocarbon, and/or by physical sputtering of the carbon or hydrocarbon material by energetic oxygen ions of the plasma. As discussed, the WAC process 80 of FIG. 3 does not employ silicon tetrachloride, and hence does not include a functional analog to the coating process 64 of the WAC process 80 of FIG. 1. Consequently, the WAC process 80 of FIG. 3 does not deposit a silicon oxide coating on interior surfaces of the plasma process chamber 10.

With continuing reference to FIG. 3, the illustrative first cleaning step 90 of the WAC process 80 employs a gas mixture comprising a mixture of nitrogen trifluoride (NF₃) gas and a carrier gas such as argon (Ar); however, a mixture of another halogen-containing gas and a carrier gas is alternatively contemplated. For example, the halogen-containing gas could instead by chlorine (Cl₂) gas which when excited to form a plasma produces chlorine ions; or hydrogen bromide (HBr) gas which when excited to form a plasma produces bromine ions; or a fluorocarbon gas which when excited to form a plasma produces fluorine ions. The fluorine ions (or other halogen ions) operate to remove silicon or silicon oxide residue 66 from surfaces of the interior 12 of the plasma process chamber 10 by chemical reaction of the fluorine ions with the silicon or silicon oxide, and/or by physical sputtering of the silicon material by energetic ions of the plasma.

The first cleaning step 90 of the WAC process 80 is modified when compared with the first cleaning step 60 of the WAC process 50 of FIG. 1 to reduce RF power and to reduce pressure in the plasma process chamber 10. This advantageously reduces the etching plasma attack on surfaces of the interior 12 of the plasma process chamber 10, and in particular reduces or eliminates plasma damage to the yttrium oxide coatings of components that are susceptible to plasma damage, such as the TCP window 20, the at least one gas injector 22, and the gas distribution plate 24. In a nonlimiting illustrative example, parameters of the first cleaning step 90 of the silicon tetrachloride-free WAC process 80 of FIG. 3 in the illustrative case of a TCP process chamber may include: chamber pressure of about 300 mTorr or less (and in some embodiments about 150 mTorr or less); TCP RF power in a range of about 500 watts to 1500 watts; TCCT setpoint in a range of about 0.9 to 3; nitrogen trifluoride gas flow rate in a range of about 5 sccm to 400 sccm; carrier argon gas flow rate in a range of about 200 sccm to 400 sccm; and process time for the first cleaning step 90 in a range of about 5 to 15 seconds. This is merely a nonlimiting illustrative example.

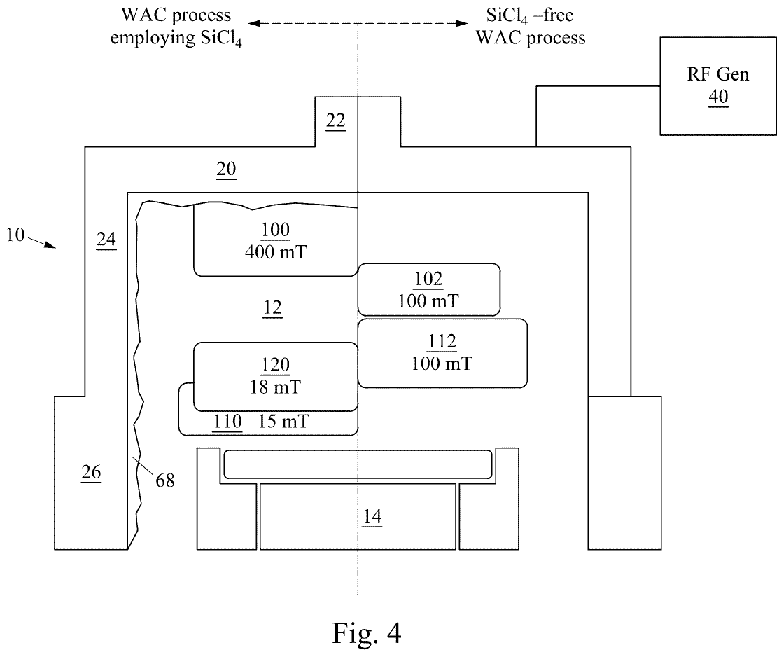

Although the yttrium oxide coatings protect surfaces of components that are susceptible to plasma damage, such as the TCP window 20, the at least one gas injector 22, and the gas distribution plate 24, the yttrium oxide coatings themselves can undergo some plasma induced damage, thereby producing yttrium oxide particles or particulates that can damage the semiconductor wafer 16 processed after the WAC cleaning process 50. By reducing RF power and pressure in the plasma process chamber 10 during the first cleaning step 90 of the silicon tetrachloride-free WAC process 80 of the embodiment of FIG. 3, the plasma is kept more centrally located within the interior volume 12 of the plasma process chamber 10 (see further description hereinbelow referencing FIG. 4) and is thus inhibited from reaching and attacking the yttrium oxide coatings, and thus advantageously reducing defect counts for the processed semiconductor wafers and improves device yield. These advantages are achieved in combination with the advantage of not using corrosive and toxic silicon tetrachloride gas, thus advantageously improving safety of the silicon tetrachloride-free WAC process 80 of the embodiment of FIG. 3. Still further, the reduced time for the first cleaning step 90 of the WAC process 80 of the embodiment of FIG. 3 compared with the first cleaning step 60 of the WAC process 50 of the embodiment of FIG. 1, along with elimination of the coating step 64 of the WAC process 50 of the embodiment of FIG. 1, results in the WAC process 80 of the embodiment of FIG. 3 being faster than the of the WAC process 50 of the embodiment of FIG. 1, thus advantageously increasing wafer throughput (e.g., by reducing the total time to process the wafer lot 46).

The illustrative second cleaning step 92 of the WAC process 80 is similar to the second cleaning step 62 of the WAC process 50 of FIG. 1, and again employs oxygen (O₂) gas. In a nonlimiting illustrative example, parameters of the second cleaning step 92 in the illustrative case of a TCP process chamber may include: chamber pressure in a range of about 5 mTorr to 300 mTorr; TCP RF power in a range of about 500-1500 watts; TCCT setpoint in a range of about 0.5 to 3; oxygen gas flow rate in a range of about 5 sccm to 400 sccm; and process time for the second cleaning step 62 in a range of about 5 seconds to 20 seconds. This is merely a nonlimiting illustrative example.

With reference now to FIG. 4, plasma distributions of the WAC process 80 of the embodiment of FIG. 3 is diagrammatically compared with plasma distributions of the WAC process 50 of the embodiment of FIG. 1. The left side of FIG. 4 depicts the plasma distributions of the WAC process 50 of the embodiment of FIG. 1, while the right side of FIG. 4 depicts the plasma distributions of the WAC process 80 of the embodiment of FIG. 3.

In the nonlimiting illustrative example of the WAC process 50 of the embodiment of FIG. 1 shown on the left side of FIG. 4, the first cleaning step 60 operates in this example at 400 mTorr chamber pressure, and produces plasma in a region 100. As seen, due to the high chamber pressure and high RF power the plasma region 100 is close to the TCP window 20. By comparison, the first cleaning step 90 of the WAC process 80 in this example operates at a lower chamber pressure of 100 mTorr, and as shown in the right side of FIG. 4 produces plasma in a region 102 that is more centrally located within the interior volume 12 of the plasma process chamber 10, and hence is not close to the TCP window 20. Said another way, the (first) plasma 102 is formed in a region in the plasma process chamber 10 that is spaced apart from the yttrium oxide-coated window 20 of the plasma process chamber 10 (and, as seen in FIG. 4, the yttrium oxide-coated window 20 includes at least one yttrium oxide-coated gas injector 22. By keeping the plasma 102 spaced apart from these yttrium oxide-coated components 20, 22, plasma damage to the yttrium oxide coatings is reduced, thus enabling the advantageous omission of subsequent silicon dioxide coating by application of a gas mixture of toxic silicon tetrachloride and oxygen (as per coating operation 64 of the WAC process 50 of FIG. 1).

As further shown on the left side of FIG. 4, the second cleaning step 62 of the WAC process 50 of the embodiment of FIG. 1 operates in this example at 15 mTorr chamber pressure, and produces plasma in a region 110 that is close to the wafer holder 14. By comparison, the second cleaning step 92 of the WAC process 80 in this example operates at a higher chamber pressure of 100 mTorr, and as shown in the right side of FIG. 4 produces plasma in a region 112 that is more centrally located within the interior volume 12 of the plasma process chamber 10, and hence is not close to the wafer holder 14.

For completeness, referring to the left side of FIG. 4, the coating step 64 of the WAC process 50 of the embodiment of FIG. 1 operates in this example at 18 mTorr chamber pressure, and produces plasma in a region 120. Since the silicon tetrachloride-free WAC process 80 of the embodiment of FIG. 3 does not include an analog to the coating step 64, there is no plasma region corresponding to region 120 shown on the right side of FIG. 4.

FIG. 4 diagrammatically depicts one particular nonlimiting illustrative example, and the plasma regions can be adjusted for a given TCP chamber by adjusting the chamber pressure and RF power during the first and second cleaning steps 90 and 92 of the WAC process 80 of the embodiment of FIG. 3. Moreover, if a different type of operative RF coupling is employed (e.g., an induction coil 42 as in the ICP chamber alternative diagrammatically indicated in FIG. 2, or an ECR connection, or deployment of RF electrodes connected by RF cables and RF feedthroughs (not shown), or so forth), then RF parameters suitable for that RF coupling may be set to provide the reduced RF power to advantageously reduce the etching plasma attack on surfaces of the interior 12 of the plasma process chamber 10, and thereby enable omission of the coating step 64 and its application of toxic silicon tetrachloride.

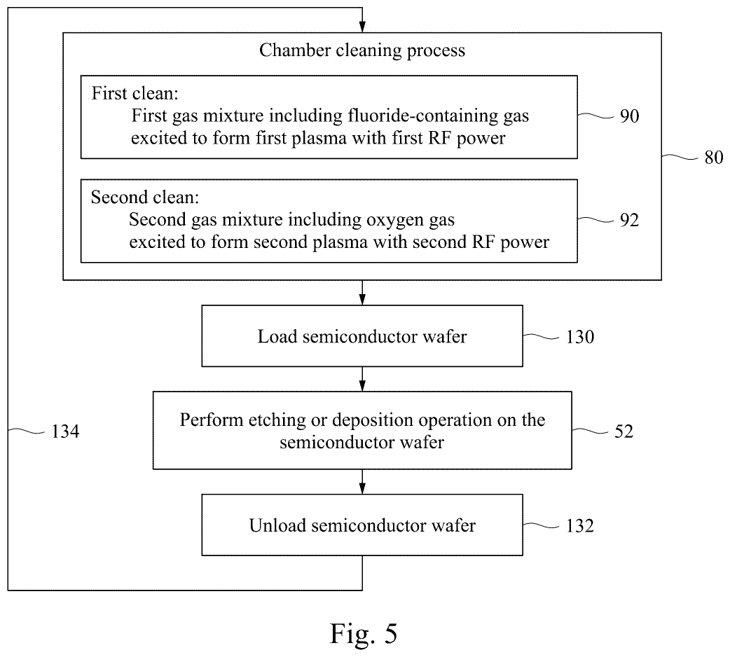

With reference now to FIG. 5, a flowchart is shown providing an alternative and more detailed depiction of the processing of the semiconductor wafers of the wafer lot 46 as shown by the time flow diagram of FIG. 3. Prior to the processing of each wafer, the silicon tetrachloride-free WAC process 80 is performed, including the first cleaning step 90 and the second cleaning step 92 as previously described. After the WAC process 80 is completed, in an operation 130 the semiconductor wafer 16 is loaded into the plasma process chamber 10. At least one plasma-assisted etching or deposition operation 52 (corresponding to one of the operations 52₁, 52₂, . . . , 52₂₅ of the time flow diagram of FIG. 3) is performed on the semiconductor wafer loaded into the plasma process chamber 10. For example, the operation 52 could be a silicon etching operation such as POEB. After the at least one plasma-assisted etching or deposition operation 52 is complete, the semiconductor wafer is unloaded in an operation 132, and as indicated by flowback arrow 134 the lot processing continues by performing the next instance of the WAC process 80 preparatory to processing the next semiconductor wafer.

In the following, some further embodiments are described.

In a nonlimiting illustrative embodiment, a method of using a plasma process chamber is disclosed. A chamber cleaning process is performed, including: flowing a gas mixture comprising nitrogen trifluoride (NF₃) gas into the plasma process chamber and exciting the NF₃ gas to form a first plasma in the plasma process chamber by applying first radio frequency (RF) power using an RF generator operatively coupled with the plasma process chamber, wherein the first plasma is formed at a pressure of 300 mTorr or less, and flowing oxygen (O₂) gas into the plasma process chamber and exciting the O₂ gas to form a second plasma in the plasma process chamber by applying second RF power using the RF generator. The method further includes, after completion of the chamber cleaning process, loading a semiconductor wafer into the plasma process chamber and performing at least one plasma operation on the semiconductor wafer in the plasma process chamber.

In a nonlimiting illustrative embodiment, a method of using a plasma process chamber is disclosed. A chamber cleaning process is performed, including: flowing a gas mixture comprising a halogen-containing gas into the plasma process chamber and exciting the halogen-containing gas to form a first plasma in the plasma process chamber by applying first RF power to the halogen-containing gas using an RF generator operatively coupled with the plasma process chamber, and flowing oxygen (O₂) gas into the plasma process chamber and exciting the O₂ gas to form a second plasma in the plasma process chamber by applying second RF power to the O₂ gas using the RF generator. The chamber cleaning process does not include flowing silicon tetrachloride (SiCl₄) into the plasma process chamber. The method further includes, after completion of the chamber cleaning process, loading a semiconductor wafer into the plasma process chamber and performing a silicon etching process on the semiconductor wafer.

In a nonlimiting illustrative embodiment, a method of cleaning a plasma process chamber is disclosed. A gas mixture comprising a halogen-containing gas is flowed into the plasma process chamber, and the halogen-containing gas is excited to form a first plasma in the plasma process chamber by applying first RF power to the halogen-containing gas using an RF generator operatively coupled with the plasma process chamber. Oxygen (O₂) gas is then flowed into the plasma process chamber, and is excited to form a second plasma in the plasma process chamber by applying second RF power to the O₂ gas using the RF generator. The first RF power is 1500 watts or less and the first plasma is formed at a pressure of 150 mTorr or less. The second plasma is formed in the plasma process chamber at a pressure of 5 mTorr or higher.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of using a plasma process chamber, the method comprising:
performing a chamber cleaning process including:
flowing a gas mixture comprising nitrogen trifluoride (NF₃) gas into the plasma process chamber and exciting the NF₃ gas to form a first plasma in the plasma process chamber by applying first radio frequency (RF) power using an RF generator operatively coupled with the plasma process chamber, wherein the first plasma is formed at a pressure of 300 mTorr or less, and
flowing oxygen (O₂) gas into the plasma process chamber and exciting the O₂ gas to form a second plasma in the plasma process chamber by applying second RF power using the RF generator; and
after completion of the chamber cleaning process, loading a semiconductor wafer into the plasma process chamber and performing at least one plasma operation on the semiconductor wafer in the plasma process chamber.

2. The method of claim 1, wherein the chamber cleaning process is performed without a semiconductor wafer loaded into the plasma process chamber during the WAC process.

3. The method of claim 1, wherein the plasma process chamber includes at least one ceramic surface that is cleaned by the chamber cleaning process.

4. The method of claim 1, wherein the first RF power is 1500 watts or less.

5. The method of claim 1, wherein the first plasma is formed in the plasma process chamber at a pressure of 150 mTorr or less.

6. The method of claim 1, wherein the second plasma is formed in the plasma process chamber at a pressure of 5 mTorr or higher.

7. The method of claim 1, wherein the first plasma is formed in a region in the plasma process chamber that is spaced apart from an yttrium oxide (Y₂O₃)-coated window of the plasma process chamber, wherein the Y₂O₃-coated window includes at least one Y₂O₃-coated gas injector.

8. The method of claim 1, wherein the at least one plasma-assisted etching or deposition operation performed on the semiconductor wafer loaded into the plasma process chamber comprises a silicon etching operation.

9. The method of claim 1, wherein the chamber cleaning process does not deposit a silicon oxide coating on interior surfaces of the plasma process chamber.

10. A method of using a plasma process chamber, the method comprising:
performing a chamber cleaning process including:
flowing a gas mixture comprising a halogen-containing gas into the plasma process chamber and exciting the halogen-containing gas to form a first plasma in the plasma process chamber by applying first radio frequency (RF) power to the halogen-containing gas using an RF generator operatively coupled with the plasma process chamber, and
flowing oxygen (O₂) gas into the plasma process chamber and exciting the O₂ gas to form a second plasma in the plasma process chamber by applying second RF power to the O₂ gas using the RF generator,
wherein the chamber cleaning process does not include flowing silicon tetrachloride (SiCl₄) into the plasma process chamber; and
after completion of the chamber cleaning process, loading a semiconductor wafer into the plasma process chamber and performing a silicon etching process on the semiconductor wafer.

11. The method of claim 10, wherein the chamber cleaning process is a wafer-less auto-clean (WAC) process performed without a semiconductor wafer loaded into the plasma process chamber.

12. The method of claim 10, wherein the halogen-containing gas comprises nitrogen trifluoride (NF₃) gas.

13. The method of claim 10, wherein the first RF power is 1500 watts or less.

14. The method of claim 10, wherein the first plasma is formed in the plasma process chamber at a pressure of between 10 mTorr and 150 mTorr.

15. The method of claim 10, wherein the second plasma is formed in the plasma process chamber at a pressure of 5 mTorr or higher.

16. The method of claim 9, wherein:
the first plasma is formed in the plasma process chamber at a pressure of between 10 mTorr and 150 mTorr,
the first RF power is 1500 watts or less, and
the second plasma is formed in the plasma process chamber at a pressure of 50 mTorr or higher.

17. The method of claim 10, wherein the first plasma is formed in a region in the plasma process chamber that is spaced apart from an yttrium oxide (Y₂O₃)-coated window of the plasma process chamber, wherein the Y₂O₃-coated window includes at least one Y₂O₃-coated gas injector.

18. The method of claim 10, wherein the silicon etching process comprises a polysilicon etch-back process.

19. A method of cleaning a plasma process chamber, the method comprising:
flowing a gas mixture comprising a halogen-containing gas into the plasma process chamber and exciting the halogen-containing gas to form a first plasma in the plasma process chamber by applying first radio frequency (RF) power to the halogen-containing gas using an RF generator operatively coupled with the plasma process chamber, and
flowing oxygen (O₂) gas into the plasma process chamber and exciting the O₂ gas to form a second plasma in the plasma process chamber by applying second RF power to the O₂ gas using the RF generator;
wherein the first RF power is 1500 watts or less and the first plasma is formed at a pressure of 150 mTorr or less; and
wherein the second plasma is formed in the plasma process chamber at a pressure of 5 mTorr or higher.

20. The method of claim 19, wherein the method of cleaning the plasma process chamber does not include depositing silicon oxide on interior surfaces of the plasma process chamber.
